(19) United States
(12) Patent Application Publication
(10) Pub. No.: US 2015/0377956 A1
(43) Pub. Date: Dec. 31, 2015

(54) METHOD AND APPARATUS FOR INLINE DEVICE CHARACTERIZATION AND TEMPERATURE PROFILING

(71) Applicant: GLOBALFOUNDRIES Inc., Grand Cayman (KY)

(72) Inventors: William MCMAHON, Scarsdale, NY (US); Andreas KERBER, Mount Kisco, NY (US); Luigi PANTISANO, Saratoga Springs, NY (US); Suresh UPPAL, Clifton Park, NY (US)

(21) Appl. No.: 14/314,693

(22) Filed: Jun. 25, 2014

(51) Int. Cl. G01R 31/28

(52) U.S. Cl. CPC G01R 31/2874

(57) ABSTRACT

A methodology for inline characterization and temperature profiling that enables parallel measurement of device characteristics at multiple temperatures and the resulting device are disclosed. Embodiments may include calibrating a first device under test (DUT) with respect to at least one heating structure in a metal layer of an integrated circuit (IC), applying a heater voltage to the at least one heating structure, and measuring at least one characteristic of the first DUT at a first temperature corresponding to the heater voltage.

### TECHNICAL FIELD

The present disclosure relates to the inline characterization of semiconductor device performance with temperature profiling. In particular, the present disclosure relates to temperature profiling of fin field effect transistors (FinFETs) and silicon on insulator (SOI) transistors.

### BACKGROUND

Inline characterization of semiconductor devices is becoming increasingly important because certain degradation mechanisms (e.g., bias temperature instability (BTI)) are relatively sensitive to the choice of manufacturing processes and materials. Accurate inline characterization at different temperatures is hindered by the time consuming process of reloading and realigning the wafer and changing the temperature of the tester. Conventional inline testing partially alleviates this problem via simultaneous testing of a few semiconductor devices but is only viable for bulk technologies.

A need therefore exists for methodology and apparatus enabling parallel measurement of device characteristics at multiple temperatures and testing of multiple devices for both FinFETs and SOI devices to significantly improve throughput.

### SUMMARY

An aspect of the present disclosure is at least one heating structure in a metal layer of an integrated circuit (IC).

Another aspect of the present disclosure is an arrangement of at least one calibrated device under test (DUT) that is directly below the at least one heating structure.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method of inline characterization, the method including: calibrating a first DUT with respect to at least one heating structure in a metal layer of an IC, applying a heater voltage to the at least one heating structure, and measuring at least one characteristic of the first DUT at a first temperature corresponding to the heater voltage.

Aspects of the present disclosure include measuring the at least one characteristic of a second DUT at a second temperature in parallel with the measurement of the at least one characteristic of the first DUT at the first temperature, the second temperature varying with the first temperature and being based on a distance of the second DUT from the first DUT. Additional aspects include calibrating a third DUT with respect to the at least one heating structure. Further aspects include determining the second temperature by interpolating the temperatures at the first DUT and the third DUT. Additional aspects include calibrating the first DUT by measuring the at least one characteristic of the first DUT at plural temperatures and plural heater voltages, and determining at least one required heater voltage to achieve a target temperature. Further aspects include the heater voltage being a differential voltage with a net zero average balance. Additional aspects include the measurement being a time zero (T0) measurement of the at least one characteristic at one or more specified temperatures. Further aspects include the at least one characteristic being a gate resistance, an activation energy (Ea), or a combination thereof, associated with the first DUT. Additional aspects include determining the at least one characteristic based on a Kelvin resistance of a gate, an external diode, a source-to-substrate diode, a drain-to-substrate diode, or a combination thereof.

Another aspect of the present disclosure is an apparatus including at least one heating structure in a metal layer of an IC and a first DUT, wherein at least a first portion of the at least one heating structure is vertically above the first DUT. Further aspects include plural second DUTs arranged in an array and a third DUT. Additional aspects include the first DUT and the third DUT being at opposite ends of the array. Further aspects include a second DUT and at least a second portion of the at least one heating structure being vertically above the second DUT. Additional aspects include plural heat sensors in different locations surrounding the at least one heating structure, the plural heat sensors determining a heating profile associated with the at least one heating structure. Further aspects include the first portion of the at least one heating structure being vertically above an active gate of the first DUT and partially covers a length of the active gate. Additional aspects include the first DUT being a SOI transistor, a FinFET, or a combination thereof.

Another aspect of the present disclosure includes a method including calibrating a heater voltage of at least one heating structure with respect to a first DUT, applying the heater voltage to the at least one heating structure, measuring at least one characteristic of the first DUT at a first temperature corresponding to the heater voltage, and measuring the at least one characteristic of plural second DUTs at plural second temperatures in parallel with the measurement of the at least one characteristic of the first DUT. Additional aspects include calibrating a third DUT with respect to the at least one heating structure. Further aspects include determining the plural second temperatures by interpolating the first temperature at the first DUT and a third temperature at the third DUT. Additional aspects include the measurement of the at least one characteristic of the first DUT and the plural second DUTs being an inline measurement.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A schematically illustrates a top view of a heating structure, in accordance with an exemplary embodiment;

FIG. 1B schematically illustrates a cross section view of a heating structure taken along the 1B-1B′ axis, in accordance with an exemplary embodiment;

FIG. 2 illustrates a process flow for the calibration of a DUT with respect to a heating structure, according to an exemplary embodiment;

FIG. 3 illustrates process flow for inline characterization and temperature profiling of one or more DUTs, according to an exemplary embodiment;

FIG. 4 illustrates a test structure layout employing multiple, fully calibrated DUTs, according to an exemplary embodiment; and

FIG. 5 schematically illustrates a top view of a test structure layout employing interpolated calibration, according to an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of poor testing throughput attendant upon inline characterization of semiconductor devices. In accordance with embodiments of the present disclosure, a heating structure is provided in a metal layer of an IC.

Methodology in accordance with embodiments of the present disclosure includes calibrating a first DUT with respect to a heating structure in a metal layer of an IC, applying a heater voltage to the heating structure, and measuring at least one characteristic of the first DUT at a first temperature corresponding to the heater voltage.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

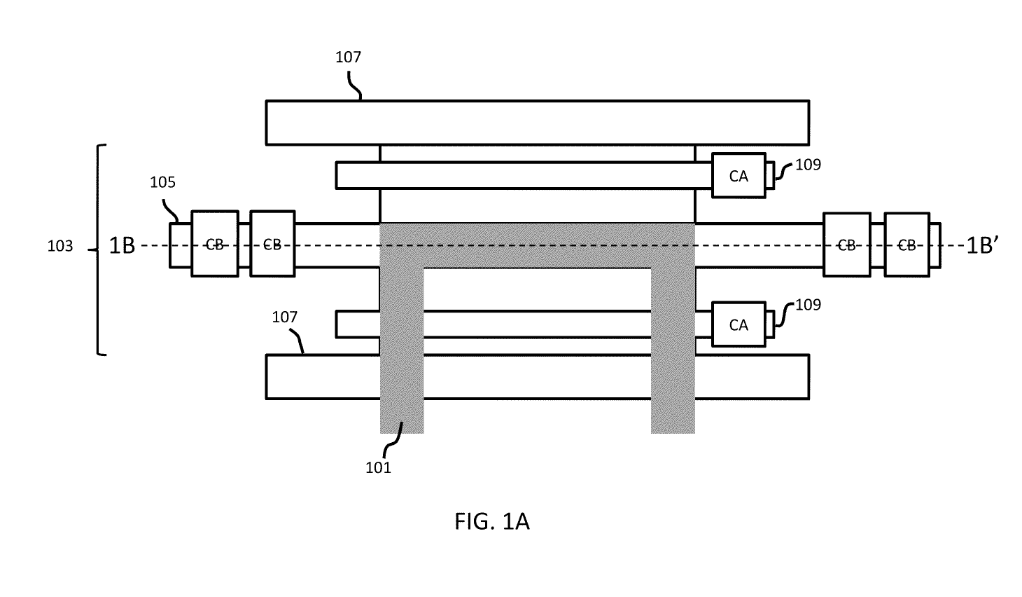

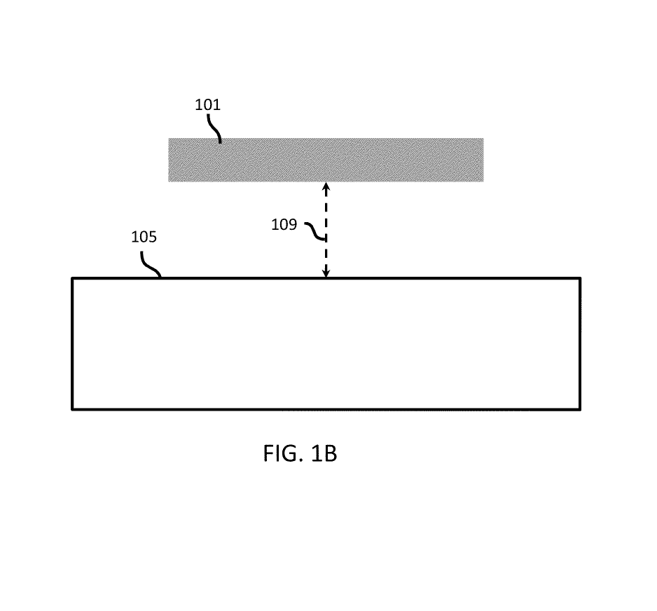

FIG. 1A schematically illustrates a top view of a heating structure, in accordance with an exemplary embodiment. Heating structure 101 may be in a first metal layer (Ml) of an IC. Directly below heating structure 101 is DUT 103. As shown, heating structure 101 may be aligned to be vertically above a portion of gate 105 (or other element) of DUT 103. DUT 103 may be any IC component or device, including a SOI transistor or FinFET. To maintain uniformity of the surrounding environment, dummy polysilicon gates 107 may be placed on either side of gate 105. Gate and source/drain contact areas (CB and CA, respectively) may be located on DUT 103 to establish contacts to the metal layer from gate 105 and trench silicide 109, respectively. Heating structure 101 may be powered by an external voltage source (not shown). For example, heating structure 101 may be connected to a differential voltage source with net zero average balance.

FIG. 1B schematically illustrates a cross section view of a heating structure taken along the 1B-1B′ axis, in accordance with an exemplary embodiment. As shown, heating structure 101 is directly above gate 105 at distance 109 and does not contact gate 105. Distance 109 may be varied as needed to suit process requirements or to obtain a desired heating profile. As indicated, heating structure 101 is comparable in size to gate 105 and, therefore, does not require a large area. Due to the close proximity of heating structure 101 to gate 105 (and DUT 103 generally), thermal isolation of heating structure 101 is not required. An insulating layer (not shown) may be present between heating structure 101 and gate 105. However, such a layer is thin enough to allow efficient heat transfer from heating structure 101 to gate 105. Gate resistance may be measured using Kelvin resistance measurement techniques. Further, the gate itself may be used as a temperature sensor or to generate heat (by applying a differential voltage across the gate).

Heating structure 101 may be used to test the impact of heat on DUT 103 under different temperature conditions. For example, following application of a heater voltage to heating structure 101, various device characteristics may be measured. Characteristics may include one or more operating parameters capable of inline measurement. For example, operating parameters may include active gate resistance, activation energy, or any unstressed standard transistor parametric information (e.g., threshold voltage, transconductance, saturation drive current (I_{dsat}), linear drive current (I_{dlin})). To obtain these measurements, additional structures may be utilized. For instance, a Kelvin connection (not shown) may be utilized between the heating structure 101 and the gate 105. Kelvin resistance measurements may be taken at an external diode (not shown) or a source/drain-to-substrate diode (not shown).

In addition to testing under specific temperature conditions, ramping temperature conditions may also be tested. A typical temperature range varies from room temperature to several hundred degrees Celsius. The time duration of ramping and, therefore, ramp rate, may be determined by the speed at which device degradation can be detected or measured. A total ramp time may range between several seconds to a minute.

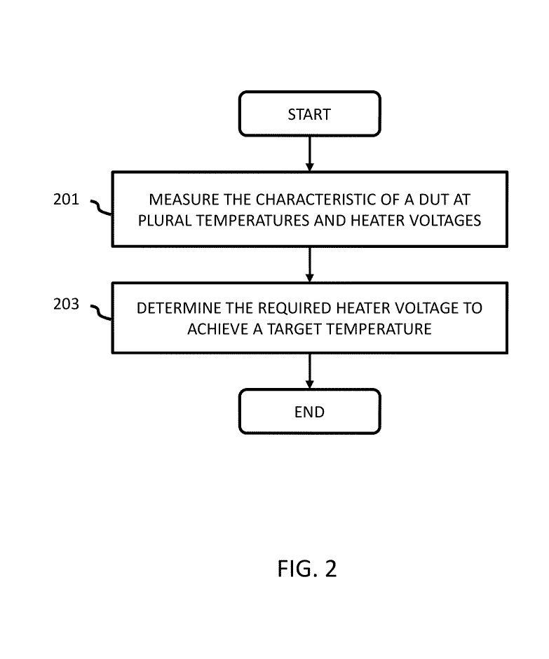

FIG. 2 illustrates a process 200 for the calibration of a DUT (e.g., DUT 103) with respect to a heating structure (e.g., heating structure 101), according to an exemplary embodiment. Calibration allows determination of specific voltages to be applied to heating structure 101 to obtain a desired temperature at a specific element (e.g., gate 105) of a DUT. In step 201, one or more characteristics are measured at specific temperatures and heater voltages. For instance, the gate resistance of DUT 103 may be measured at several temperatures. Next, the gate resistance may be measured at various voltages at room temperature. Based on the collected data, the voltage required to hit a specific temperature target may be determined (step 203).

To improve the accuracy of calibration, additional measurements may be made with different DUTs. For example, device variability may be taken into account by collecting the same data on multiple DUTs. The effect of distance 111 on testing may be taken into account by making measurements at different distances 111.

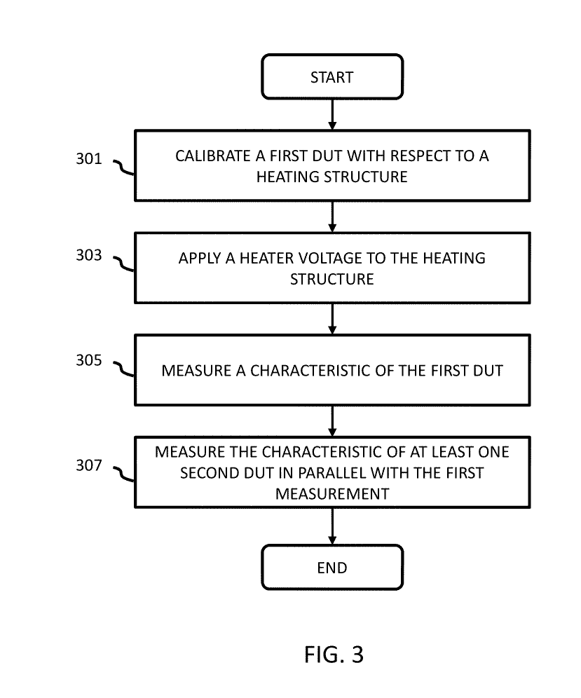

FIG. 3 illustrates process 300 for inline characterization and temperature profiling of one or more DUTs, according to an exemplary embodiment. In step 301, a first DUT (e.g., DUT 103) is calibrated with respect to a heating structure (e.g., heating structure 101). In step 303, a voltage is applied to the heating structure. Various voltage application scenarios are possible. For example, the voltage may be applied to hit specific temperature targets. Alternatively, a ramping differential voltage may be applied such that the temperature is increased smoothly or in graduated steps. The rate of temperature increase/decrease may also be varied to produce more or less rapid temperature changes. In each scenario, a stress bias may be applied to the DUT during testing to test device degradation (e.g., parametric or breakdown) as a function of applied voltage.

In step 305, one or more characteristics of the first DUT are measured. As previously discussed, these characteristics may include active gate resistance, activation energy, or unstressed operating parameters of the first DUT. The measurements may be made at the DUTs in parallel and at various temperatures. For example, the measurements may be made continuously as a function of a ramping differential voltage applied to the heating structure in the presence of a stress bias applied at the DUT. The measurements may be made at discrete intervals or continuously as the heater voltage (and temperature) is varied.

The measurements at the first DUT may be made in parallel with additional measurements at one or more second DUTs. Parallel measurement refers, for instance, to the simultaneous measurement of characteristics at multiple DUTs in a single test environment. It allows for increased testing throughput because multiple measurements can be collected simultaneously over a range of temperature conditions. Test conditions may be closely monitored using temperature sensors placed in surrounding locations.

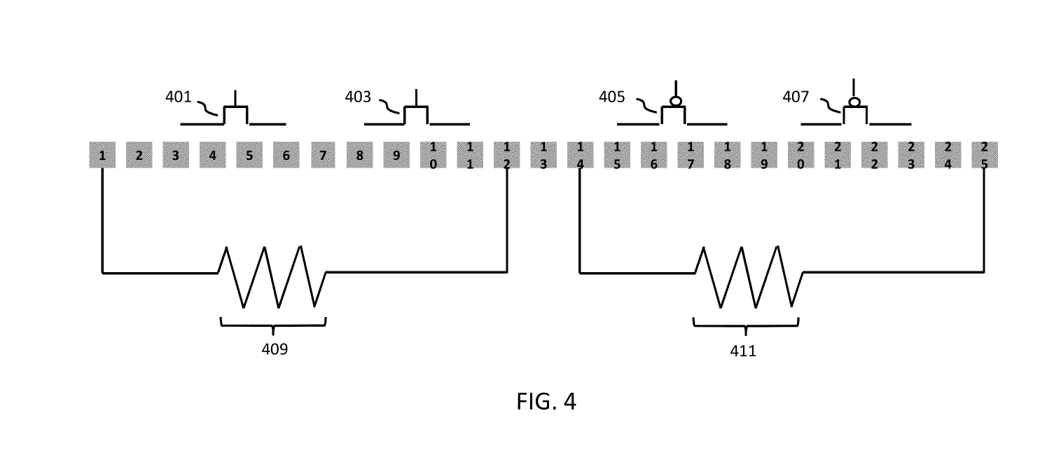

FIG. 4 illustrates a test structure layout employing multiple, fully calibrated DUTs, according to an exemplary embodiment. As shown, DUTs 401 through 403 may be n-FET transistors and DUTs 405 through 407 may be p-FET transistors. As indicated, a single heater 409 applies heat to DUTs 401 through 403. Similarly, a single heater 411 applies heat to DUTs 405 through 407. All DUTs 401 through 407 are fully calibrated with respect to heaters 409 and 411. As indicated, heaters 409 and 411 may be resistive elements.

As further indicated, heaters 409 and 411 utilize pin connections, which belong to a metal layer. For example, the following pin connections may be utilized in the layout illustrated in FIG. 4.

TABLE 1

| Device Terminal | Pins |
|---|---|
| Heater 409 | 1, 12 |
| Heater 411 | 14, 25 |
| Shared substrate/source | 13 |
| DUT 401 gate | 3, 4, 5, 6 |
| DUT 403 gate | 8, 9, 10, 11 |
| DUT 405 gate | 15, 16, 17, 18 |
| DUT 407 gate | 20, 21, 22, 23 |
| DUT 401 drain | 2 |
| DUT 403 drain | 7 |
| DUT 405 drain | 19 |
| DUT 407 drain | 24 |

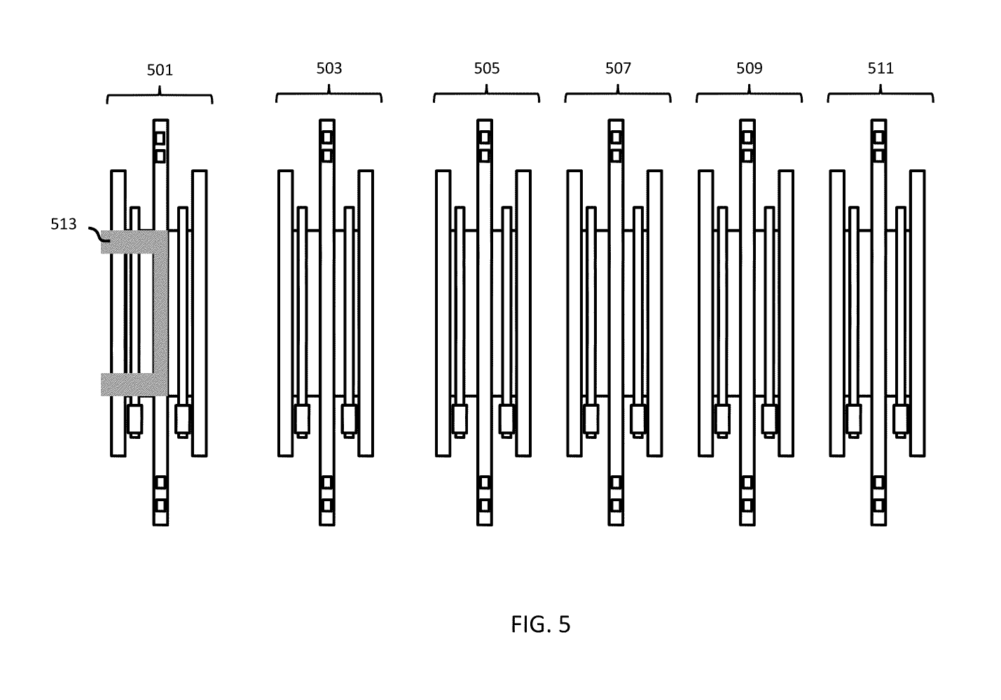

Testing throughput may be further scaled by placing DUTs in an array arrangement and utilizing interpolated calibration. FIG. 5 schematically illustrates a top view of a test structure layout employing interpolated calibration, according to an exemplary embodiment. As shown, DUTs 501 through 511 are arranged in an evenly spaced array with a single heating structure 513 directly above first DUT 501. This array arrangement need only be calibrated with respect to DUTs 501 and 511. Temperatures at intervening DUTs 503 through 509 may be determined by linear interpolation of the temperatures at DUTs 501 and 511. The following pin connections may be utilized in the layout illustrated in FIG. 5.

TABLE 2

| Device Terminal | Pins |
|---|---|
| Heater | 1, 12 |
| Substrate/source | 13 |
| DUT 501 gate (calibrated) | 3, 4, 5, 6 |
| DUT 511 gate (calibrated) | 8, 9, 10, 11 |
| DUT 501 drain (calibrated) | 2 |
| DUT 511 drain (calibrated) | 7 |
| DUT 503 through 509 drains | 12, 15, 17, 19, 21, 23 |
| (interpolated) | |

In addition to increasing test throughput, the arrangements illustrated in FIGS. 4 and 5 allow T0 inline characterization without requiring changes to the temperature of the tester. For example, T0 inline measurements at DUTs 501 through 511 at multiple temperatures may be performed simultaneously. In addition, T0 device performance may be measured by monitoring activation energy during temperature ramping. In this manner, the impact of process technology on activation energy may be determined because the activation energy may be measured on all process splits.

The embodiments of the present disclosure can achieve several technical effects, including in situ heating for inline characterization and temperature profiling of both SOI and FinFET devices. The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
calibrating a first device under test (DUT) with respect to at least one heating structure in a metal layer of an integrated circuit (IC);
applying a heater voltage to the at least one heating structure; and
measuring at least one characteristic of the first DUT at a first temperature corresponding to the heater voltage.

2. The method of claim 1, further comprising:
measuring the at least one characteristic of a second DUT at a second temperature in parallel with the measurement of the at least one characteristic of the first DUT at the first temperature,
wherein the second temperature varies with the first temperature based on a distance of the second DUT from the first DUT.

3. The method of claim 2, further comprising:
calibrating a third DUT with respect to the at least one heating structure.

4. The method of claim 3, further comprising:
determining the second temperature by interpolating the temperatures at the first DUT and the third DUT.

5. The method of claim 1, comprising calibrating the first DUT by:
measuring the at least one characteristic of the first DUT at plural temperatures and plural heater voltages; and
determining at least one required heater voltage to achieve a target temperature.

6. The method of claim 1, wherein the heater voltage is a differential voltage with a net zero average balance.

7. The method of claim 1, wherein the measurement is a time zero (T0) measurement of the at least one characteristic at one or more specified temperatures.

8. The method of claim 1, wherein the at least one characteristic is a gate resistance, an activation energy (Ea), or a combination thereof, associated with the first DUT.

9. The method of claim 1, comprising determining the at least one characteristic based on a Kelvin resistance of a gate, an external diode, a source-to-substrate diode, a drain-to-substrate diode, or a combination thereof.

10. An apparatus comprising:
at least one heating structure in a metal layer of an integrated circuit (IC); and
a first device under test (DUT),
wherein at least a first portion of the at least one heating structure is vertically above the first DUT.

11. The apparatus of claim 10, further comprising:
plural second DUTs arranged in an array; and
a third DUT.

12. The apparatus of claim 11, wherein the first DUT and the third DUT are at opposite ends of the array.

13. The apparatus of claim 10, further comprising:
a second DUT,
wherein at least a second portion of the at least one heating structure is vertically above the second DUT.

14. The apparatus of claim 10, further comprising:
plural heat sensors in different locations surrounding the at least one heating structure,
wherein the plural heat sensors determine a heating profile associated with the at least one heating structure.

15. The apparatus of claim 10, wherein the first portion of the at least one heating structure is vertically above an active gate of the first DUT and partially covers a length of the active gate.

16. The apparatus of claim 10, wherein the first DUT is a silicon-on-insulator (SOI) transistor, a fin field effect transistor (FinFET), or a combination thereof.

17. A method comprising:
calibrating a heater voltage of at least one heating structure with respect to a first device under test (DUT);
applying the heater voltage to the at least one heating structure;
measuring at least one characteristic of the first DUT at a first temperature corresponding to the heater voltage; and
measuring the at least one characteristic of plural second DUTs at plural second temperatures in parallel with the measurement of the at least one characteristic of the first DUT.

18. The method of claim 17, further comprising:
calibrating a third DUT with respect to the at least one heating structure.

19. The method of claim 18, further comprising:
determining the plural second temperatures by interpolating the first temperature at the first DUT and a third temperature at the third DUT.

20. The method of claim 17, wherein the measurement of the at least one characteristic of the first DUT and the plural second DUTs is an inline measurement.
